(19) United States
(12) Patent Application Publication
(10) Pub. No.: US 2024/0297146 A1
(43) Pub. Date: Sep. 5, 2024

(54) METHOD FOR MANUFACTURING SEMICONDUCTOR DEVICE, METHOD FOR MANUFACTURING SUPPORT SUBSTRATE, AND METHOD FOR PEELING SUBSTRATE

(71) Applicant: Kioxia Corporation, Tokyo (JP)

(72) Inventors: Shota KONUMA, Yokkaichi Mie (JP); Hiroshi FUJITA, Yokohama Kanagawa (JP); Hisashi KATO, Yokkaichi Mie (JP); Naomi YANAI, Kuwana Mie (JP)

(73) Assignee: Kioxia Corporation, Tokyo (JP)

(21) Appl. No.: 18/589,254

(22) Filed: Feb. 27, 2024

(30) Foreign Application Priority Data
Mar. 1, 2023 (JP) 2023-030650

(51) Int. Cl. H01L 23/00; H01L 21/265; H01L 21/324; H10B 80/00

(52) U.S. Cl. CPC H01L 24/96; H01L 21/2652; H01L 21/324; H10B 80/00; H01L 2224/96

(57) ABSTRACT

According to one embodiment, a method for manufacturing a semiconductor device includes forming, on a substrate, an active layer in which a dopant is implanted; forming a porous layer by making the active layer porous by an anodization treatment; forming a device layer including at least a part of a configuration of the semiconductor device above the porous layer; and cleaving the porous layer to remove the substrate.

### CROSS-REFERENCE TO RELATED APPLICATIONS

This application is based upon and claims the benefit of priority from Japanese Patent Application No. 2023-030650, filed on Mar. 1, 2023; the entire contents of which are incorporated herein by reference.

### FIELD

Embodiments described herein relate generally to a method for manufacturing a semiconductor device, a method for manufacturing a support substrate, and a method for peeling a substrate.

### BACKGROUND

A semiconductor device such as a three-dimensional nonvolatile memory may be configured by bonding a support substrate on which a plurality of memory pillars is formed and a semiconductor substrate on which a peripheral circuit is formed. After the bonding with the semiconductor substrate, the support substrate is peeled off and reused. A porous layer is provided on the support substrate, and the support substrate is peeled off by cleaving the porous layer.

The porous layer is formed on the support substrate by, for example, anodization or the like. However, there is a problem that the thickness of the porous layer becomes non-uniform in the plane of the support substrate.

### BRIEF DESCRIPTION OF THE DRAWINGS

FIG. 1 is a cross-sectional view illustrating a configuration example of a semiconductor memory device according to a first embodiment;

FIGS. 2A to 2C are diagrams sequentially illustrating a part of the procedure of the method for manufacturing a support substrate according to the first embodiment;

FIGS. 3A to 3D are diagrams sequentially illustrating a part of the procedure of the method for manufacturing the support substrate according to the first embodiment;

FIG. 4 is a cross-sectional view illustrating an example of a configuration of the support substrate according to the first embodiment;

FIGS. 5A to 5C are cross-sectional views sequentially illustrating a part of the procedure of a method for manufacturing the semiconductor memory device according to the first embodiment;

FIGS. 6A to 6B are cross-sectional views sequentially illustrating a part of the procedure of the method for manufacturing the semiconductor memory device according to the first embodiment;

FIGS. 7A to 7B are cross-sectional views sequentially illustrating a part of the procedure of the method for manufacturing the semiconductor memory device according to the first embodiment;

FIGS. 8A to 8E are cross-sectional views sequentially illustrating a part of the procedure of the method for manufacturing the semiconductor memory device according to the first embodiment;

FIGS. 9A to 9E are cross-sectional views illustrating a part of the procedure of the regenerating process of the support substrate according to the first embodiment;

FIGS. 10A and 10B are cross-sectional views illustrating a part of the procedure of a porous layer forming process according to a comparative example;

FIG. 11 is a graph illustrating a relationship between the sheet resistance of an active layer formed using the method for manufacturing a support substrate according to the first embodiment and the formation speed and the porous diameter of the porous layer formed in the active layer;

FIGS. 12A to 12D are cross-sectional views illustrating a part of the procedure of a method for manufacturing the support substrate according to a first modification of the first embodiment;

FIGS. 13A to 13D are cross-sectional views illustrating a part of the procedure of a method for manufacturing the support substrate according to a second modification of the first embodiment;

FIGS. 14A to 14B are cross-sectional views illustrating a part of the procedure of a method for manufacturing the semiconductor memory device according to the second modification of the first embodiment;

FIGS. 15A to 15D are cross-sectional views illustrating a part of the procedure of a method for manufacturing a support substrate according to a second embodiment;

FIGS. 16A to 16B are cross-sectional views sequentially illustrating a part of the procedure of a method for manufacturing the semiconductor memory device according to the second embodiment;

FIGS. 17A to 17C are cross-sectional views sequentially illustrating a part of the procedure of the method for manufacturing the semiconductor memory device according to the second embodiment;

FIGS. 18A to 18C are cross-sectional views sequentially illustrating a part of the procedure of a method for manufacturing the semiconductor memory device according to a modification of the second embodiment; and

FIGS. 19A to 19B are cross-sectional views sequentially illustrating a part of the procedure of the method for manufacturing the semiconductor memory device according to the modification of the second embodiment.

### DETAILED DESCRIPTION

In general, according to one embodiment, a method for manufacturing a semiconductor device includes forming, on a substrate, an active layer in which a dopant is implanted; forming a porous layer by making the active layer porous by an anodization treatment; forming a device layer including at least a part of a configuration of the semiconductor device above the porous layer; and cleaving the porous layer to remove the substrate.

Exemplary embodiments of the present invention will be explained below in detail with reference to the accompanying drawings. Note that the present invention is not limited by the following embodiments. In addition, constituent elements in the following embodiments include those that can be easily assumed by those skilled in the art or those that are substantially the same.

### First Embodiment

Hereinafter, a first embodiment will be described in detail with reference to the drawings.

### (Configuration Example of Semiconductor Memory Device)

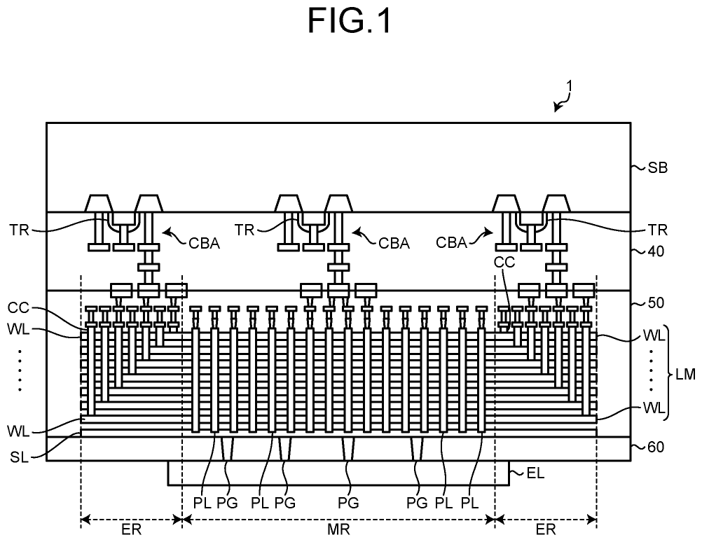

FIG. 1 is a cross-sectional view illustrating a configuration example of a semiconductor memory device 1 according to a first embodiment. However, in FIG. 1, hatching is omitted in consideration of visibility of the drawing.

As illustrated in FIG. 1, the semiconductor memory device 1 includes an electrode film EL, a source line SL, and a stacked body LM in which a plurality of word lines WL is stacked in order from the lower side of the drawing. In addition, the semiconductor memory device 1 includes a peripheral circuit CBA provided on a semiconductor substrate SB as a first semiconductor substrate above the stacked body LM.

The source line SL is disposed on the electrode film EL via an insulating layer 60. The source line SL is, for example, a polysilicon layer or the like.

A plurality of plugs PG are disposed in the insulating layer 60, and the source line SL and the electrode film EL maintain electrical conduction via the plugs PG. As a result, the source potential can be applied to the source line SL from the outside of the semiconductor memory device 1 via the electrode film EL and the plug PG.

The stacked body LM in which the word lines WL as a plurality of second conductive layers are stacked is disposed on the source line SL. A memory region MR is disposed in a central portion of the stacked body LM, and contact regions ER are disposed at both ends of the stacked body LM.

In the memory region MR, pillars PL as a plurality of memory pillars penetrating the word line WL in the stacking direction are disposed. A plurality of memory cells is formed at intersections of the pillars PL and the word lines WL. As a result, the semiconductor memory device 1 is configured as, for example, a three-dimensional nonvolatile memory in which the memory cells are three-dimensionally disposed in the memory region MR.

In the contact region ER, a plurality of contacts CC connected to each of the plurality of word lines WL is disposed. In the present specification, in the extending direction of the contact CC, the connection end side of the contact CC with the word line WL is referred to as a lower side of the semiconductor memory device 1.

From the contact CC, a write voltage, a read voltage, and the like are applied to a memory cell included in the memory region MR at the central portion of the stacked body LM via the word line WL at the same height position as the memory cell. In this manner, the word lines WL stacked in multiple layers are individually drawn out by these contacts CC.

The plurality of word lines WL, pillars PL, and contacts CC are covered with an insulating layer 50. The insulating layer 50 also extends around the plurality of word lines WL.

A semiconductor substrate SB as the first semiconductor substrate above the insulating layer 50 is, for example, a silicon substrate or the like. A peripheral circuit CBA including a transistor TR, wiring, and the like is disposed on the surface of the semiconductor substrate SB. Various voltages applied from the contacts CC to the memory cells are controlled by the peripheral circuit CBA electrically connected to the contacts CC. In this manner, the peripheral circuit CBA controls the electrical operation of the memory cell.

The peripheral circuit CBA is covered with an insulating layer 40, and the insulating layer 40 and the insulating layer 50 covering the stacked body LM are joined to each other, thereby forming the semiconductor memory device 1 including the configuration of the plurality of word lines WL, the pillars PL, the contacts CC, and the like, and the peripheral circuit CBA.

### (Method for Manufacturing Semiconductor Memory Device)

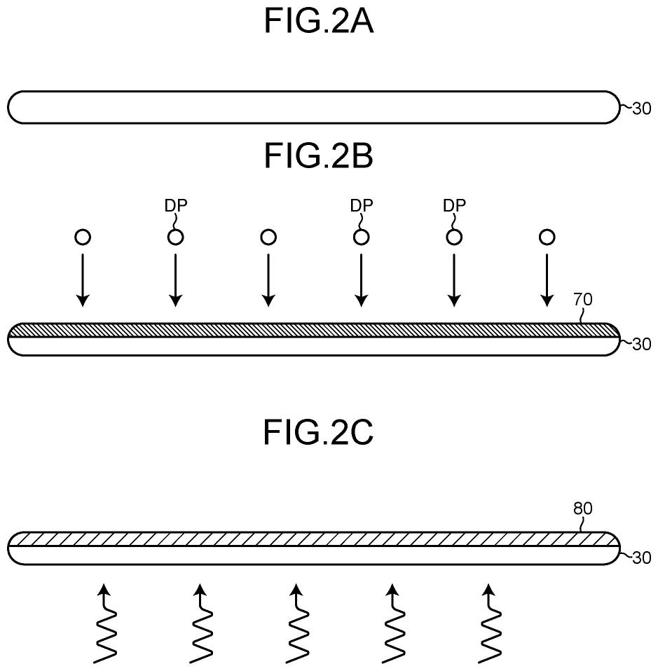

Next, a method for manufacturing the semiconductor memory device 1 according to the first embodiment will be described with reference to FIGS. 2A to 9E. Note that the method for manufacturing the semiconductor memory device 1 partially includes a method for manufacturing the support substrate SS and a method for peeling the support substrate SS.

First, the support substrate SS that supports the semiconductor memory device 1 in the middle of manufacture and how the support substrate SS is manufactured are illustrated in FIGS. 2A to 4.

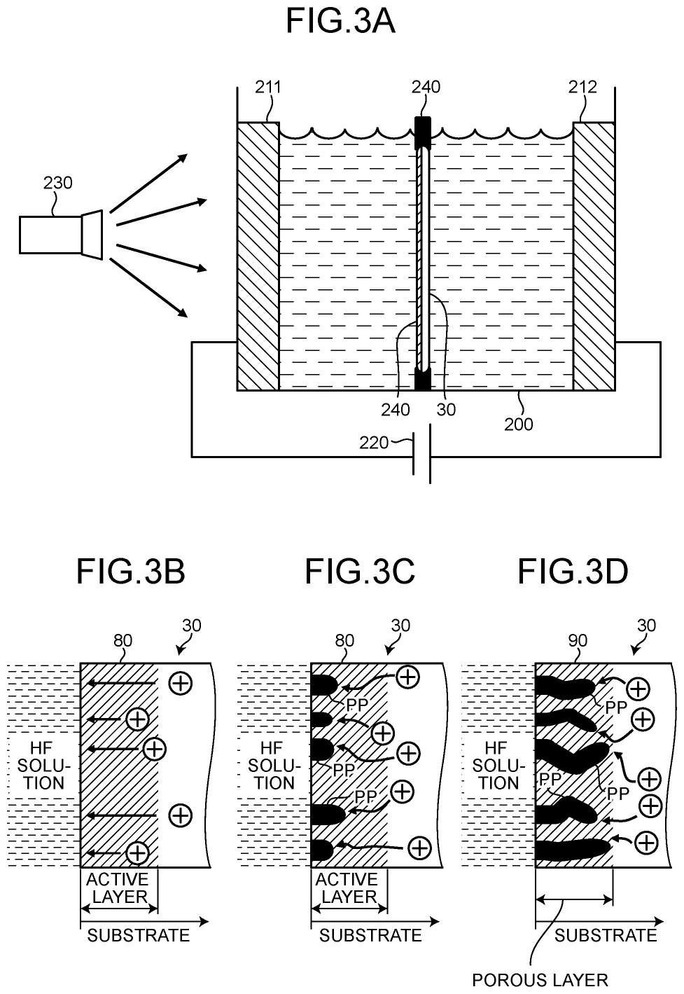

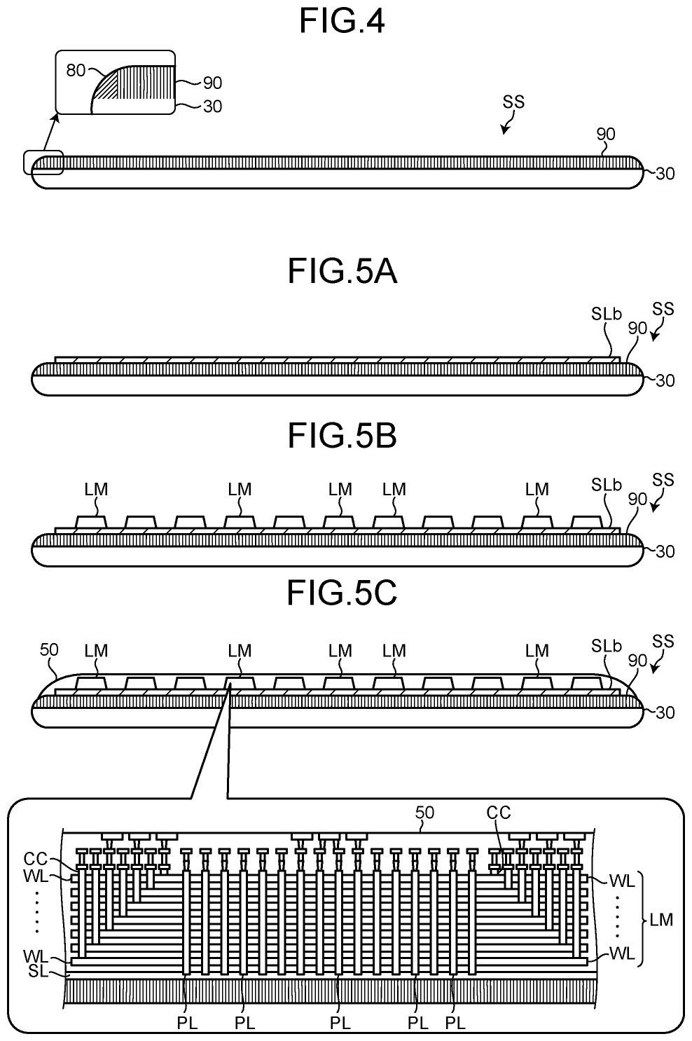

FIGS. 2A to 3D are diagrams sequentially illustrating a part of the procedure of the method for manufacturing the support substrate SS (see FIG. 4) according to the first embodiment. In the method for manufacturing the support substrate SS described below, as illustrated in FIG. 4, the support substrate SS having a porous layer 90 on the upper surface is manufactured.

As illustrated in FIG. 2A, a semiconductor substrate 30 as a second semiconductor substrate such as a silicon substrate is prepared.

As illustrated in FIG. 2B, a dopant DP is implanted into the upper surface of the semiconductor substrate 30 by ion implantation or the like to form an impurity layer 70.

At this time, as the dopant DP, a p-type dopant such as boron, indium, or gallium, an n-type dopant such as phosphorus, arsenic, or antimony, or the like can be used.

The dopant DP preferably reaches a depth of 10 nm or more and 10,000 nm or less from the surface of the semiconductor substrate 30 depending on the thickness of the porous layer 90 which is desired to be formed on the support substrate SS. The implantation depth of the dopant DP can be adjusted, for example, by changing the acceleration energy of ions at the time of implantation of the dopant DP. That is, the implantation depth of the dopant DP increases as the acceleration energy increases.

As illustrated in FIG. 2C, the semiconductor substrate 30 on which the impurity layer 70 is formed is annealed to form the active layer 80 in which the dopant DP in the impurity layer 70 is activated. When annealing is performed, a vertical furnace, a rapid thermal anneal (RTA) using an infrared lamp, or the like can be used.

In addition, since the implantation depth of the dopant DP into the semiconductor substrate 30 also changes by adjusting the annealing temperature and the processing time, it is possible to further control the thickness of the porous layer 90.

As described above, by implanting the dopant DP into the semiconductor substrate 30 and activating the dopant DP, the active layer 80 having a resistance value lower than the original resistance value of the semiconductor substrate 30 is formed.

The resistivity of the semiconductor substrate 30 is, for example, 20 Ωcm to 30 Ωcm. On the other hand, the resistivity of the active layer 80 is, for example, 0.1 Ωcm or less, and more preferably 0.0017 Ωcm or more and 0.015 Ωcm or less. When the resistivity of the active layer 80 is, for example, less than 0.0017 Ωcm, unevenness may conversely occur in the porous layer 90 when the active layer 80 is thereafter made porous to form the porous layer 90.

The resistivity of the active layer 80 can be controlled by changing the type, implantation amount, and the like of the dopant DP.

The implantation of the dopant DP illustrated in FIG. 2B may be performed a plurality of times. The implantation depth and the implantation amount of the dopant DP can also be adjusted by performing the implantation of the dopant DP a plurality of times.

As illustrated in FIG. 3A, the active layer 80 is made porous, for example, by anodization. Note that FIG. 3A illustrates an example of using a single wafer type method of processing the semiconductor substrates 30 one by one. However, the method of performing the anodization treatment on the semiconductor substrate 30 is not limited to the single wafer type, and for example, other methods such as a batch type may be used.

When the semiconductor substrate 30 is subjected to the anodization treatment, the semiconductor substrate 30 is immersed in a chemical solution tank 200 filled with an isopropyl alcohol solution of hydrofluoric acid. At this time, it is preferable to seal the edge portion of the semiconductor substrate 30 with a sealing material 240. A light source 230 that emits, for example, ultraviolet light or the like is provided on the side of the chemical solution tank 200.

In addition, a cathode 211 is immersed in the chemical solution tank 200 so as to face the surface of the semiconductor substrate 30 on which the active layer 80 is formed. The cathode 211 is, for example, a mesh-like platinum electrode or the like. In the chemical solution tank 200, an anode 212 such as a platinum electrode is provided so as to face the cathode 211 across the semiconductor substrate 30. The hydrofluoric acid solution is separated between the cathode 211 side and the anode 212 side by the sealing material 240 described above.

In the above state, a DC voltage is applied from a DC power supply 220 between the cathode 211 and the anode 212. As a result, in the semiconductor substrate 30, the active layer 80 is mainly made porous and the porous layer 90 is formed.

FIGS. 3B to 3D illustrate details of how the active layer 80 is made porous.

As illustrated in FIG. 3B, when a DC voltage is applied between the cathode 211 and the anode 212, positive charges in the semiconductor substrate 30 are attracted toward the cathode 211.

As illustrated in FIG. 3C, silicon or the like constituting the semiconductor substrate 30 is oxidized by positive charges attracted to the surface of the semiconductor substrate 30 facing the cathode 211. Furthermore, the silicon oxide is dissolved by hydrofluoric acid in the hydrofluoric acid solution, and the porous PP is formed on the surface of the semiconductor substrate 30.

As illustrated in FIG. 3D, the reaction of generating silicon oxide by positive charges and the reaction of dissolving silicon oxide by hydrofluoric acid proceed toward the inside of the semiconductor substrate 30, whereby the porous PP also extends into the semiconductor substrate 30.

Reaction equations assumed to occur when the porous PP is formed by the processing of FIGS. 3B to 3D are shown below.

Si+2HF+2h⁺→SiF₂+2H⁺

SiF₂+2HF→SiF₄+H₂↑

SiF₄+2HF→H₂SiF₆

Here, positive charges are likely to concentrate in the active layer 80 having a lower resistance value than the other regions of the semiconductor substrate 30, and the formation speed of the porous PP is dramatically improved as compared with the other regions of the semiconductor substrate 30.

Furthermore, when the dopant DP in the active layer 80 is p-type, the active layer 80 can be a main source of such positive charges in the semiconductor substrate 30. Therefore, the porous formation in the active layer 80 is further promoted.

In a case where the dopant DP in the active layer 80 is n-type, the above-described reaction on the surface of the active layer 80 can be promoted by light assist. That is, the semiconductor substrate 30 is irradiated with ultraviolet light from the light source 230 provided above the chemical solution tank 200. The ultraviolet light from the light source 230 passes through, for example, the mesh-shaped cathode 211 and is applied to the semiconductor substrate 30. As a result, silicon or the like on the surface of the active layer 80 is photoexcited, and the oxidation reaction is promoted.

As described above, when the tip portion of the porous PP formed at a high rate in the active layer 80 reaches the interface between the active layer 80 and the other region of the semiconductor substrate 30, the formation speed is extremely decreased, and the reaction related to the formation of the porous PP is substantially stopped. Thereby, the porous layer 90 is formed exclusively in the active layer 80 with a relatively uniform layer thickness.

As described above, the support substrate SS of the first embodiment is manufactured.

FIG. 4 is a cross-sectional view illustrating an example of a configuration of the support substrate SS according to the first embodiment. As illustrated in FIG. 4, the support substrate SS has a configuration in which the porous layer 90 is disposed in a surface layer portion of the semiconductor substrate 30 such as a silicon substrate.

As described above, since the porous layer 90 is mainly formed in the active layer 80 portion, the thickness of the porous layer 90 is equal to that of the active layer 80 or slightly thicker than the active layer 80, for example, 10 nm or more and 10,000 nm or less. In addition, the porous layer 90 has a relatively uniform layer thickness over the entire surface of the support substrate SS, and in the case of the porous layer 90 having a thickness of 10,000 nm, for example, the in-plane layer thickness difference of the support substrate SS is less than 60 nm, more preferably less than 40 nm.

In addition, as described above, since the porous layer 90 is formed on the active layer 80 having a resistivity of, for example, 0.1 Ωcm or less, more preferably 0.0017 Ωcm or more and 0.015 Ωcm or less, the porous layer 90 having a substantially uniform porosity and porous diameter is obtained. The porosity of the porous layer 90 is preferably, for example, 40% or more and 60% or less, and the porous diameter is preferably 5 nm or more and 10 nm or less. Here, the porosity is the ratio of the volume of voids to the entire porous layer 90, that is, the porosity.

As described above, in the anodization treatment, the edge of the semiconductor substrate 30 may be sealed with the sealing material 240. Therefore, as illustrated in the enlarged cross-sectional view of FIG. 4, a part of the active layer 80 that has not been subjected to the anodization treatment may remain in a region of about 2 mm in width at the edge portion of the semiconductor substrate 30.

Next, a state in which the semiconductor memory device 1 is manufactured using the support substrate SS is illustrated in FIGS. 5A to 7B.

FIGS. 5A to 7B are cross-sectional views sequentially illustrating a part of the procedure of the method for manufacturing the semiconductor memory device 1 according to the first embodiment.

As illustrated in FIG. 5A, a conductive layer SLb is formed on the porous layer 90 of the support substrate SS. The conductive layer SLb as a first conductive layer is, for example, a polysilicon layer or the like, and later becomes the source line SL of the semiconductor memory device 1. However, in forming the conductive layer SLb on the porous layer 90, the conductive layer SLb may be formed via another layer such as a silicon oxide layer or a polysilicon layer. The layer interposed between the porous layer 90 and the conductive layer SLb may be a one-layer structure, a multilayer structure of the same kind of layer, a multilayer structure of a different kind of layer, or the like.

As illustrated in FIG. 5B, a plurality of stacked bodies LM in which the plurality of word lines WL is stacked is formed on the conductive layer SLb. As illustrated in the enlarged cross-sectional view of FIG. 5C, a plurality of pillars PL, a plurality of contacts CC, and the like are formed in each stacked body LM.

The stacked body LM in which the pillars PL, the contacts CC, and the like are formed is formed as follows. That is, a stacked body in which a plurality of silicon nitride layers and a plurality of silicon oxide layers are alternately stacked one by one is formed on the conductive layer SLb formed on the support substrate SS.

In addition, a plurality of contact holes reaching individual silicon nitride layers are formed in a partial region of the stacked body. In addition, a memory hole penetrating the stacked body and reaching the conductive layer SLb is formed, and the memory hole is filled with a memory layer, a semiconductor layer, and the like. At this time, the memory layer on the side surface of the semiconductor layer is partially removed to electrically connect the semiconductor layer and the conductive layer SLb.

Thereafter, word lines WL are formed by replacing the plurality of silicon nitride layers of the stacked body with conductive layers by processing called replacement processing. In addition, the plurality of contact holes is filled with a conductive layer or the like to form a contact CC, and an upper layer wiring or the like is formed on the upper layer of the stacked body LM.

Note that the configuration illustrated in the enlarged view of FIG. 5C is an example of a device layer formed above the porous layer 90. Also, the device layer may also include at least a first layer.

As illustrated in FIG. 5C, the insulating layer 50 covering the plurality of stacked bodies LM in which the plurality of pillars PL, the plurality of contacts CC, and the like are formed as described above is formed. Electrode pads electrically connected to the pillars PL, the contacts CC, and the like of the stacked body LM are formed on the surface of the insulating layer 50.

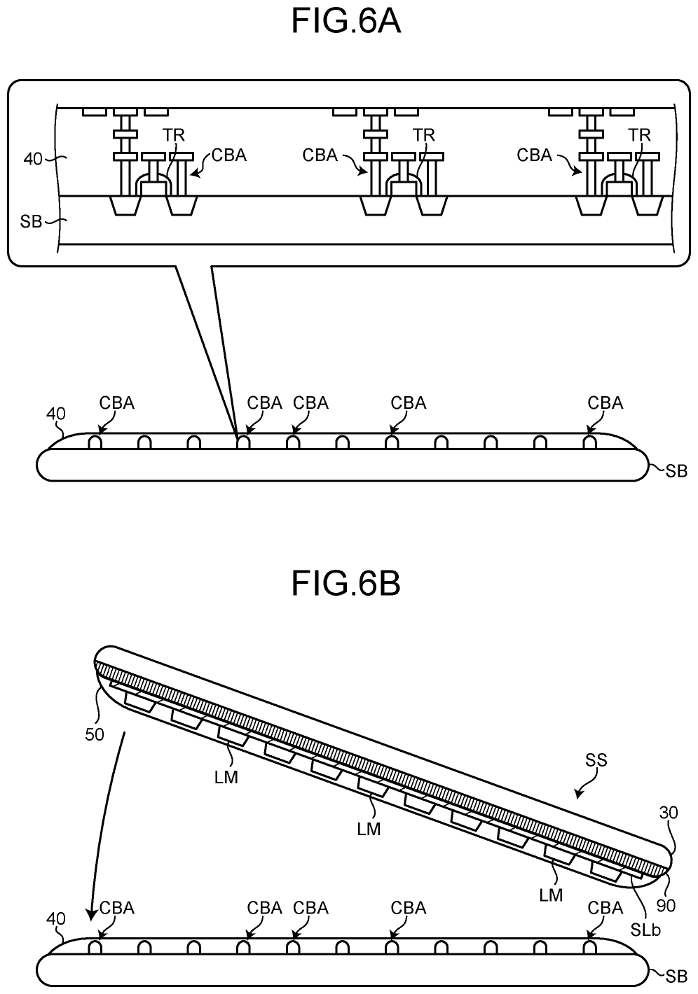

As illustrated in FIG. 6A, a plurality of peripheral circuits CBA including the transistors TR are formed on a semiconductor substrate SB separate from the support substrate SS. The plurality of peripheral circuits CBA is formed so as to respectively correspond to, for example, the plurality of stacked bodies LM. In addition, the insulating layer 40 covering the peripheral circuit CBA is formed. An electrode pad electrically connected to the transistor TR and the like of the peripheral circuit CBA is formed on the surface of the insulating layer 40.

As illustrated in FIG. 6B, the surface of the support substrate SS on which the stacked body LM and the like are formed is opposed to the surface of the semiconductor substrate SB on which the peripheral circuit CBA and the like are formed, the insulating layer 50 on the support substrate SS side and the insulating layer 40 on the semiconductor substrate SB side are bonded, and the support substrate SS and the semiconductor substrate SB are attached together.

These insulating layers 50 and 40 can be bonded by, for example, activating their surfaces in advance by plasma treatment or the like. When the insulating layers 50 and 40 are bonded, the support substrate SS and the semiconductor substrate SB are aligned so that the electrode pad formed on the insulating layer 50 and the electrode pad formed on the insulating layer 40 overlap each other.

After the insulating layers 50 and 40 are bonded, an annealing treatment is performed to bond both electrode pads by, for example, Cu—Cu bonding. As a result, the stacked body LM and the peripheral circuit CBA corresponding to each other are electrically connected, and the support substrate SS and the semiconductor substrate SB are bonded together.

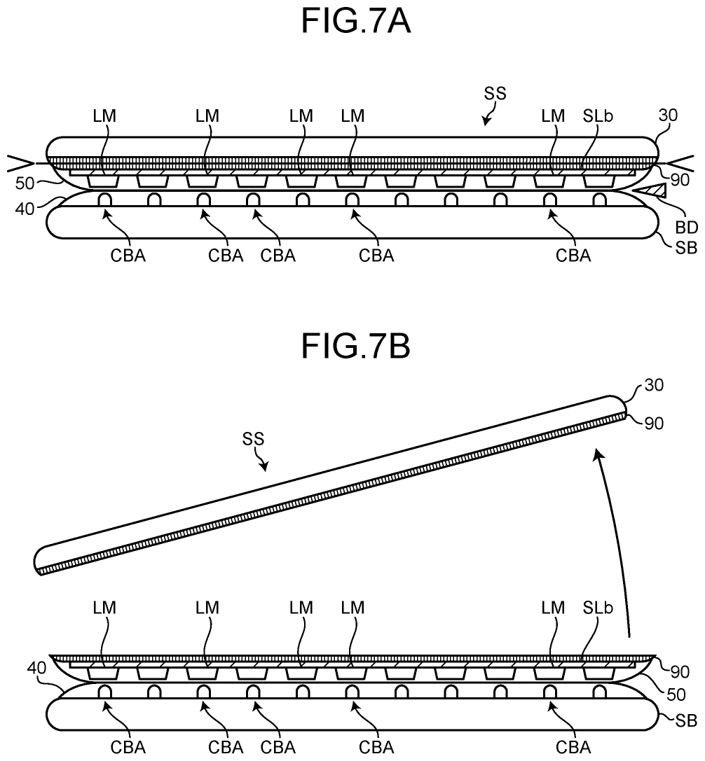

As illustrated in FIG. 7A, the porous layer 90 is cleaved from one end portion of the support substrate SS. The porous layer 90 can be cleaved by, for example, inserting a blade BD into the bonding surface between the support substrate SS and the semiconductor substrate SB or injecting water jet. As a result, a crack occurs on the bonding surface between the support substrate SS and the semiconductor substrate SB. The crack extends toward the porous layer 90 at the outer peripheral portion where the partial structure of the semiconductor memory device 1 such as the stacked body LM is not disposed. When the crack reaches the porous layer 90 that is more fragile than the other layers, the crack further extends along the porous layer 90, so that the porous layer 90 is cleaved.

As described above, when sealing is performed on the semiconductor substrate 30 at the time of anodization, the active layer 80 remaining without being made porous may exist at the edge portion of the semiconductor substrate 30. However, since the active layer 80 is mainly present in the non-bonded portion of the semiconductor substrate 30, it does not interfere with cleavage of the porous layer 90.

As illustrated in FIG. 7B, the support substrate SS is peeled off from the configuration including the stacked body LM in which the plurality of pillars PL, the plurality of contacts CC, and the like are formed.

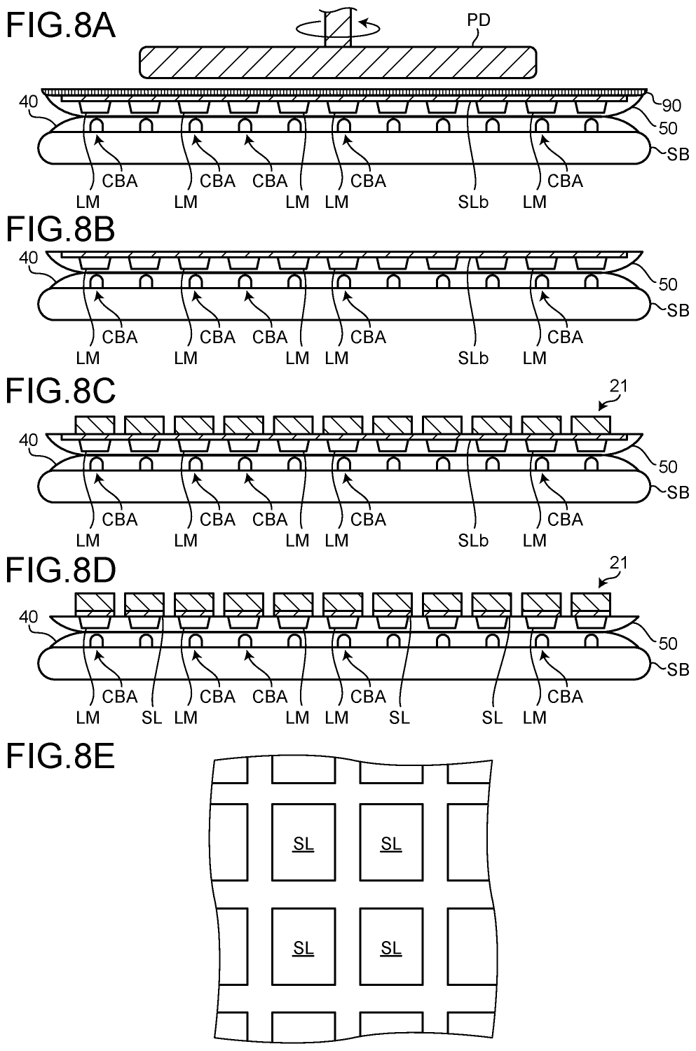

As illustrated in FIG. 8A, the porous layer 90 remaining on the conductive layer SLb side of the stacked body LM bonded on the semiconductor substrate SB is ground and removed using a polishing pad PD by chemical mechanical polishing (CMP) or the like.

As illustrated in FIG. 8B, the porous layer 90 is ground and removed, so that the conductive layer SLb is exposed on the upper surface of the semiconductor substrate SB.

As illustrated in FIG. 8C, a resist pattern 21 having a pattern corresponding to the arrangement of each stacked body LM is formed on the conductive layer SLb.

As illustrated in FIG. 8D, the conductive layer SLb is etched through the resist pattern 21 to form a pattern of a plurality of source lines SL separated for each stacked body LM.

As illustrated in FIG. 8E, for example, in accordance with the arrangement of the plurality of stacked bodies LM arranged in a grid shape in the plane of the semiconductor substrate SB, the source line SL is also formed in a grid pattern, for example.

After the source lines SL are formed in a plurality of patterns, the resist pattern 21 is removed by ashing processing using oxygen plasma or the like.

Thereafter, the electrode film EL connected to the source line SL via the plug PG formed in the insulating layer 60 is formed, and the semiconductor substrate SB is divided so as to include at least one stacked body LM, whereby the semiconductor memory device 1 of the first embodiment is manufactured.

On the other hand, the support substrate SS peeled off from the semiconductor substrate SB is subjected to a regenerating process described below and reused as the support substrate SS used for manufacturing a new semiconductor memory device 1.

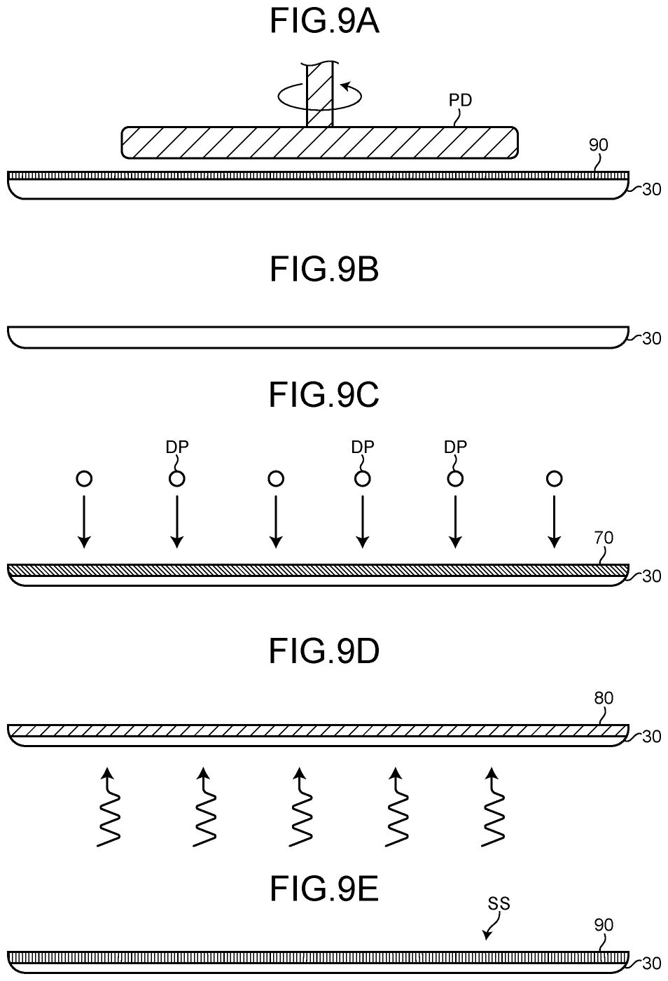

FIGS. 9A to 9E are cross-sectional views illustrating a part of the procedure of the regenerating process of the support substrate SS according to the first embodiment.

As illustrated in FIG. 9A, the porous layer 90 remaining on the support substrate SS side due to cleavage is ground and removed using the polishing pad PD. The porous layer 90 may be removed by wet etching or the like.

As illustrated in FIG. 9B, the porous layer 90 is ground and removed to obtain the semiconductor substrate 30 having a flat surface and slightly thinner than the original semiconductor substrate 30.

Thereafter, the processing illustrated in FIGS. 2A to 3D is performed on the semiconductor substrate 30.

That is, as illustrated in FIG. 9C, the dopant DP is implanted into the upper surface of the semiconductor substrate 30 to form the impurity layer 70, as illustrated in FIG. 9D, the active layer 80 is formed by annealing, and as illustrated in FIG. 9E, the porous layer 90 is formed mainly on the active layer 80 by anodization.

As described above, the support substrate SS is regenerated from the used semiconductor substrate 30. The regenerating process of the support substrate SS illustrated in FIGS. 9A to 9E may also be included in the method for manufacturing the support substrate SS.

### Overview

A semiconductor memory device such as a three-dimensional nonvolatile memory may be manufactured by, for example, forming a stacked body including a plurality of pillars on a support substrate and bonding the stacked body to a semiconductor substrate on which a peripheral circuit is separately formed. The support substrate is bonded to the semiconductor substrate and then peeled off to be repeatedly reused.

For example, a porous layer is formed on the support substrate in advance, and the support substrate is peeled off by cleaving the porous layer. The porous layer is formed by, for example, subjecting a semiconductor substrate serving as a support substrate to an anodization treatment. However, the porous layer formed on the semiconductor substrate by anodization has a problem that the variation in layer thickness in the plane of the semiconductor substrate is large.

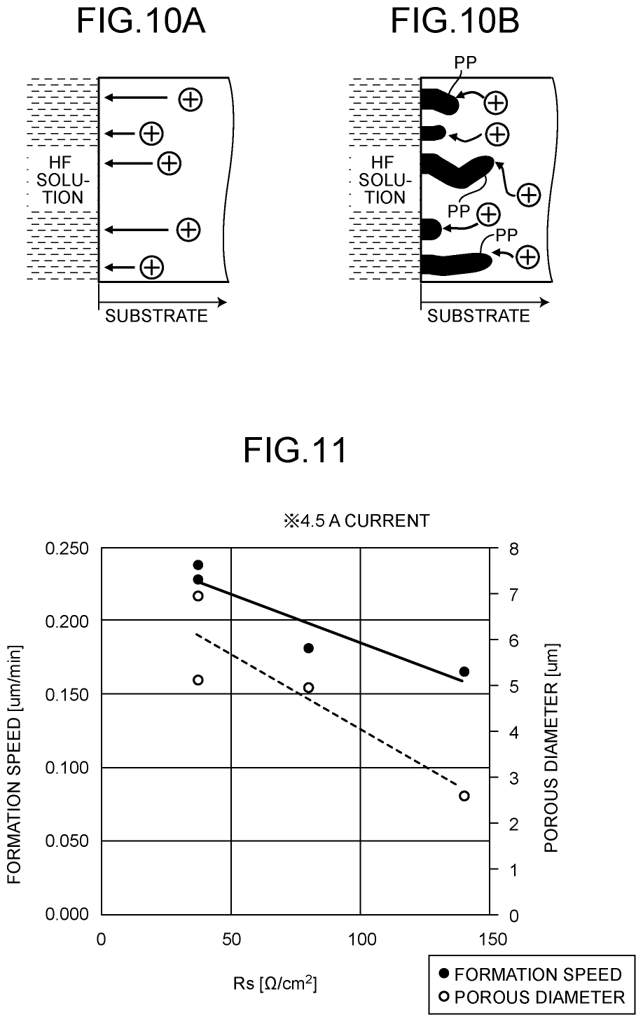

FIGS. 10A and 10B are cross-sectional views illustrating a part of the procedure of a porous layer forming process according to a comparative example. As illustrated in FIG. 10A, when the semiconductor substrate is immersed in a hydrofluoric acid solution and a DC voltage is applied, positive charges in the semiconductor substrate are attracted to a surface of the semiconductor substrate facing the cathode side. As a result, as illustrated in FIG. 10B, an oxidation reaction of silicon constituting the semiconductor substrate, a dissolution reaction of silicon oxide by hydrofluoric acid, and the like proceed, and the porous PP extends into the semiconductor substrate.

At this time, the thickness of the porous layer is adjusted by the value of the DC voltage applied to the semiconductor substrate, the treatment time of anodization, and the like. However, the formation speed of the porous PP in the semiconductor substrate is extremely slow, and the thickness of the porous layer may become uneven in the plane of the semiconductor substrate. In the case of a porous layer having a thickness of 10000 nm, for example, the difference in layer thickness in the plane of the semiconductor substrate may be 60 nm or more.

The present inventors have found that the formation speed of the porous by anodization is increased by decreasing the resistance value of the semiconductor substrate. Based on the finding, the present inventors have considered that, for example, by implanting a dopant into the surface layer of the semiconductor substrate and activating the dopant, the resistance value from the surface of the semiconductor substrate to a predetermined depth can be reduced, and by selectively forming the portion into a porous state, the uniformity of the layer thickness in the surface of the porous layer can be improved.

FIG. 11 is a graph illustrating a relationship between the sheet resistance of the active layer formed using the method for manufacturing the support substrate SS according to the first embodiment and the formation speed and the porous diameter of the porous layer formed in the active layer.

The horizontal axis of the graph of FIG. 11 is the sheet resistance Rs (Ω/cm²) of the active layer. The left vertical axis of the graph of FIG. 11 is the formation speed (μm/min) of the porous layer, and the right vertical axis is the porous diameter (nm) of the porous layer. When the porous was formed on the active layer, the value of direct current in anodization was set to 4.5 amperes.

As illustrated in FIG. 11, it is found that the lower the sheet resistance Rs of the active layer, the higher the porous formation speed. In addition, it is found that the porous diameter increases as the sheet resistance Rs of the active layer decreases. That is, by decreasing the sheet resistance Rs of the active layer, the porosity can be increased.

The porous diameter in the graph of FIG. 11 can be measured by, for example, spectroscopic ellipsometry, a gas adsorption method, or the like. The porosity can also be obtained by the spectroscopic ellipsometry, the gas adsorption method, or the like.

According to the method for manufacturing a support substrate of the first embodiment, the active layer 80 is formed by implanting the dopant DP into the surface of the semiconductor substrate 30 and is activated, and the active layer 80 is made porous by anodization treatment to form the porous layer 90. Thus, can improve the uniformity of the layer thickness of the porous layer 90.

According to the method for manufacturing the support substrate of the first embodiment, when the active layer 80 is formed, the layer thickness of the active layer 80 is controlled by controlling acceleration energy for implanting the dopant DP. Thereby, the porous layer 90 can be formed to a desired thickness.

According to the method for manufacturing the support substrate of the first embodiment, the resistance value of the active layer 80 is controlled by controlling the implantation amount of the dopant DP. Thereby, the porous layer 90 can be formed at a desired formation speed and adjusted to a desired porosity.

According to the method for manufacturing the support substrate of the first embodiment, when the active layer 80 is formed, the dopant DP is implanted a plurality of times. This makes it possible to more precisely control the implantation depth and the implantation amount of the dopant DP. By controlling the implantation depth of the dopant DP, the thickness of the porous layer 90 can be controlled as described above. In addition, the resistivity of the active layer 80 is adjusted by controlling the implantation amount of the dopant DP, and as described above, the porous layer 90 can be formed at a desired formation speed and can be adjusted to a desired porosity.

According to the method for manufacturing the support substrate of the first embodiment, the porous layer 90 is cleaved to peel off the semiconductor substrate 30, and the surface of the peeled semiconductor substrate 30 is planarized and regenerated. As a result, the used support substrate SS can be regenerated and repeatedly reused. By repeatedly reusing the support substrate SS, the manufacturing cost of the semiconductor memory device 1 can be reduced.

In the first embodiment described above, for example, the implantation amount of the dopant DP in the active layer 80 is made as uniform as possible, and the porous layer 90 having a substantially uniform porosity is formed. However, by making the implantation amount of the dopant DP different in the depth direction of the active layer 80, the porous layer 90 in which the porosity changes in the layer direction may be formed.

In this case, for example, the implantation amount of the dopant DP can be increased in the depth direction of the active layer 80, and the porosity can be increased in the depth direction of the porous layer 90. Stress is likely to be generated inside the porous layer 90, and the porous layer 90 is more easily cleaved.

### (First Modification)

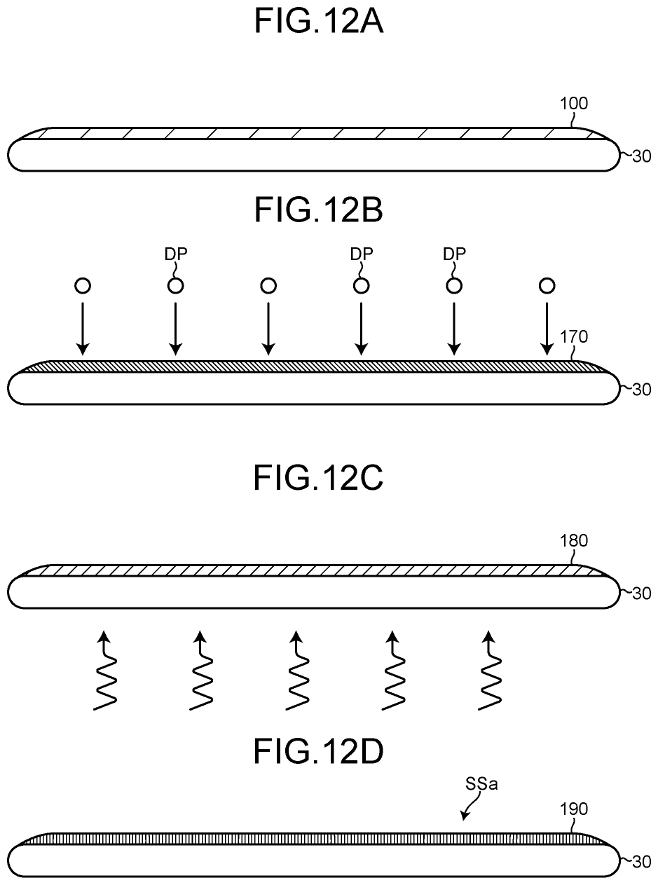

Next, a support substrate SSa of a first modification of the first embodiment will be described with reference to FIGS. 12A to 12D. The support substrate SSa of the first modification is different from that of the first embodiment described above in that a porous layer 190 is formed on a semiconductor layer 100 on the semiconductor substrate 30.

FIGS. 12A to 12D are cross-sectional views illustrating a part of the procedure of the method for manufacturing the support substrate SSa according to the first modification of the first embodiment. In the following drawings, the same reference numerals are given to the same configurations as those of the first embodiment described above, and the description thereof may be omitted.

As illustrated in FIG. 12A, the semiconductor layer 100 is formed on an upper surface of the semiconductor substrate 30 such as a silicon substrate. The semiconductor layer 100 is, for example, a polysilicon layer or an amorphous silicon layer formed by a chemical vapour deposition (CVD) method or the like. Alternatively, the semiconductor layer 100 may be a single crystal silicon layer or the like obtained by epitaxially growing a silicon crystal on the upper surface of the semiconductor substrate 30.

Note that, in a case where the semiconductor layer 100 is a polysilicon layer, an amorphous silicon layer, or the like formed by a CVD method or the like, a substrate of another material can be used instead of the semiconductor substrate 30. Examples of the other substrate include an insulating substrate such as a ceramic substrate or a quartz substrate, and a conductive substrate such as a sapphire substrate or a metal substrate.

The thickness of the semiconductor layer 100 can be, for example, 10 nm or more and 10000 nm or less.

As illustrated in FIG. 12B, the dopant DP is implanted into the semiconductor layer 100 to form the impurity layer 170. The implantation depth of the dopant DP can be equal to or less than the thickness of the semiconductor layer 100, and may be, for example, 10 nm or more and 10000 nm or less.

As illustrated in FIG. 12C, the semiconductor substrate 30 on which the impurity layer 170 is formed is annealed to activate the dopant DP, thereby forming the active layer 180.

As illustrated in FIG. 12D, the semiconductor substrate 30 on which the active layer 180 is formed is subjected to an anodization treatment in the same manner as in the first embodiment described above, and the active layer 180 is mainly made porous to form a porous layer 190 on the upper surface of the semiconductor substrate 30.

As described above, the support substrate SSa of the first modification is manufactured.

According to the method for manufacturing the support substrate SSa of the first modification, when the active layer 180 is formed, the semiconductor layer 100 is formed on the semiconductor substrate 30, and the dopant DP is implanted into the semiconductor layer 100 and activated.

As described above, the active layer 180 formed on the semiconductor substrate 30 is made porous to form the porous layer 190, so that the semiconductor substrate 30 itself is not subjected to the grinding treatment when the support substrate SSa after use is regenerated. As a result, wear of the semiconductor substrate 30 can be reduced, and the number of times of reuse of the support substrate SSa can be increased. Therefore, the manufacturing cost of the semiconductor memory device 1 can be further reduced.

Note that the configuration of the first modification of the first embodiment described above can also be applied in combination with the configuration of a second modification of the first embodiment described below, the configuration of the second embodiment or the modification, or the like.

### (Second Modification)

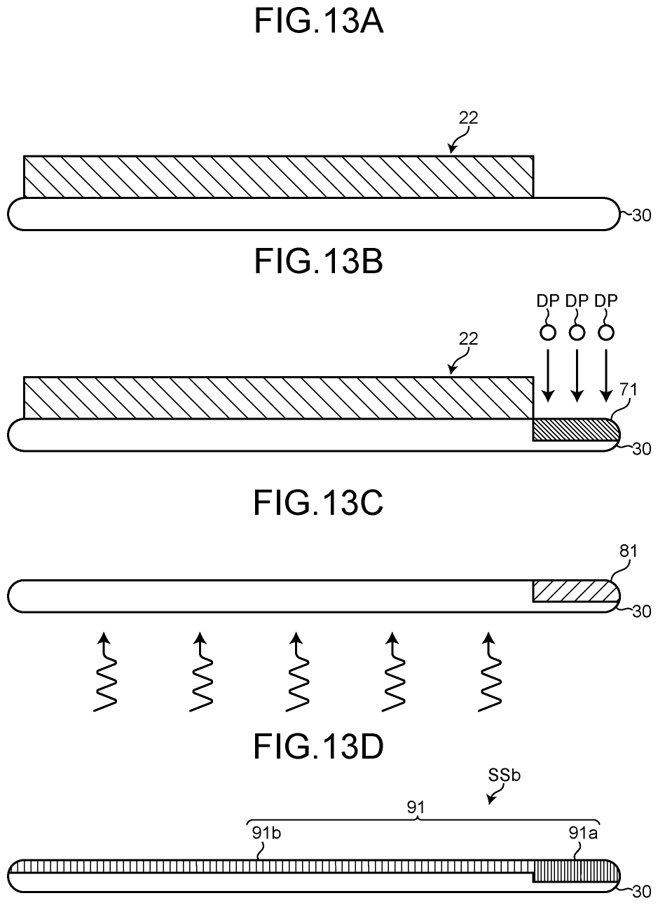

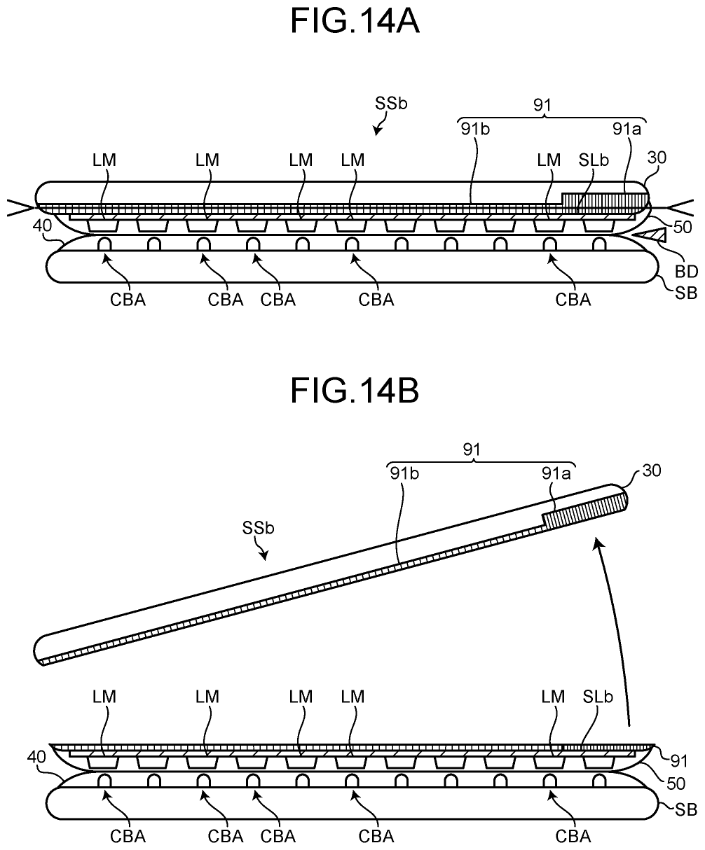

Next, a support substrate SSb of the second modification of the first embodiment will be described with reference to FIGS. 13A to 14B. The support substrate SSb of second modification is different from that of the first embodiment described above in that the porosity of the porous layer 91 is made different in a plane.

Note that in the following drawings, the same reference numerals are given to the same configurations as those of the above-described first embodiment, and the description thereof may be omitted.

FIGS. 13A to 13D are cross-sectional views illustrating a part of the procedure of the method for manufacturing the support substrate SSb according to the second modification of the first embodiment.

As illustrated in FIG. 13A, a resist pattern 22 having an opening at one end portion of semiconductor substrate 30 is formed.

As illustrated in FIG. 13B, the dopant DP is implanted into a portion of the semiconductor substrate 30 exposed from the resist pattern 22 to form an impurity layer 71 at one end portion of the semiconductor substrate 30. Thereafter, the resist pattern 22 is removed by ashing processing using oxygen plasma or the like.

As illustrated in FIG. 13C, the semiconductor substrate 30 having the impurity layer 71 formed at one end portion is annealed to activate the dopant DP in the impurity layer 71, thereby forming the active layer 81.

As illustrated in FIG. 13D, the semiconductor substrate 30 having the active layer 81 formed at one end portion is subjected to an anodization treatment in the same manner as in the first embodiment described above to form a porous layer 91 on the upper surface of the semiconductor substrate 30. The porous layer 91 includes a porous layer 91a in which the active layer 81 is made porous at least at one end portion of the semiconductor substrate 30. The porous layer 91 may also include a porous layer 91b in which the upper surface of the semiconductor substrate 30 is made porous in a region excluding the one end portion where the porous layer 91a is formed.

In this case, the porous layer 91b in which the semiconductor substrate 30 having an unadjusted resistance value is made porous is formed to have a lower porosity and a smaller layer thickness than the porous layer 91a in which the low-resistance active layer 81 is made porous. At this time, the porosity of the porous layer 91a is preferably, for example, 50% or more and 65% or less, and the porosity of the porous layer 91b is preferably, for example, 40% or more and 50% or less.

As described above, the support substrate SSb of the second modification is manufactured.

After the processing of FIG. 13B, the dopant DP may be implanted again into the entire surface of the semiconductor substrate 30 to form an active layer in which the implantation amount of the dopant DP at one end portion of the semiconductor substrate 30 is higher than that in the other region. This also makes it possible to form a porous layer having a higher porosity at one end portion of the semiconductor substrate 30 than in other regions.

In addition, an ion implantation device capable of adjusting the in-plane distribution of the implantation amount of the dopant DP may be used at the time of ion implantation. In this case, the implantation amount of the dopant DP can be made different in the plane of the semiconductor substrate 30 by using the function of the ion implantation device without forming the resist pattern 22 or the like.

As described above, since the support substrate SSb has the porous layer 91 having a high porosity at one end portion of the semiconductor substrate 30, peeling of the support substrate SSb is facilitated when a semiconductor memory device is manufactured.

FIGS. 14A to 14B are cross-sectional views illustrating a part of the procedure of a method for manufacturing the semiconductor memory device according to the second modification of the first embodiment.

As illustrated in FIG. 14A, after the support substrate SSb on which the plurality of stacked bodies LM having the plurality of pillars PL, the plurality of contacts CC, and the like are formed is bonded to the semiconductor substrate SB, a blade BD is inserted into the bonding surface between the support substrate SSb and the semiconductor substrate SB from one end portion side of the support substrate SSb on which the porous layer 91a having a higher porosity than the other is formed, or the water jet is injected.

As illustrated in FIG. 14B, as described above, the entire porous layer 91 is cleaved starting from the porous layer 91a at one end portion of the support substrate SSb, and the support substrate SSb is peeled off.

According to the method for manufacturing the support substrate SSb of the second modification, when the active layer 81 is formed, the implantation amount of the dopant DP in the edge region on one end side of the semiconductor substrate 30 is made higher than the implantation amount of the dopant DP in the other region, and when the porous layer 91 is formed, the porosity of the one end side of the semiconductor substrate 30 is higher than the porosity of the other region.

As a result, the porous layer 91 can be cleaved with one end side of the support substrate SSb as a starting point, and the support substrate SSb can be easily peeled off. In addition, damage to the semiconductor substrate 30 when the support substrate SSb is peeled off is reduced, and the number of times of reuse of the support substrate SSb can be increased.

### Second Embodiment

Hereinafter, a second embodiment will be described in detail with reference to the drawings. The second embodiment is different from the first embodiment in that source lines are formed in a predetermined pattern using a porous layer formed on a support substrate as a mask.

Note that in the following drawings, the same reference numerals are given to the same configurations as those of the above-described first embodiment, and the description thereof may be omitted.

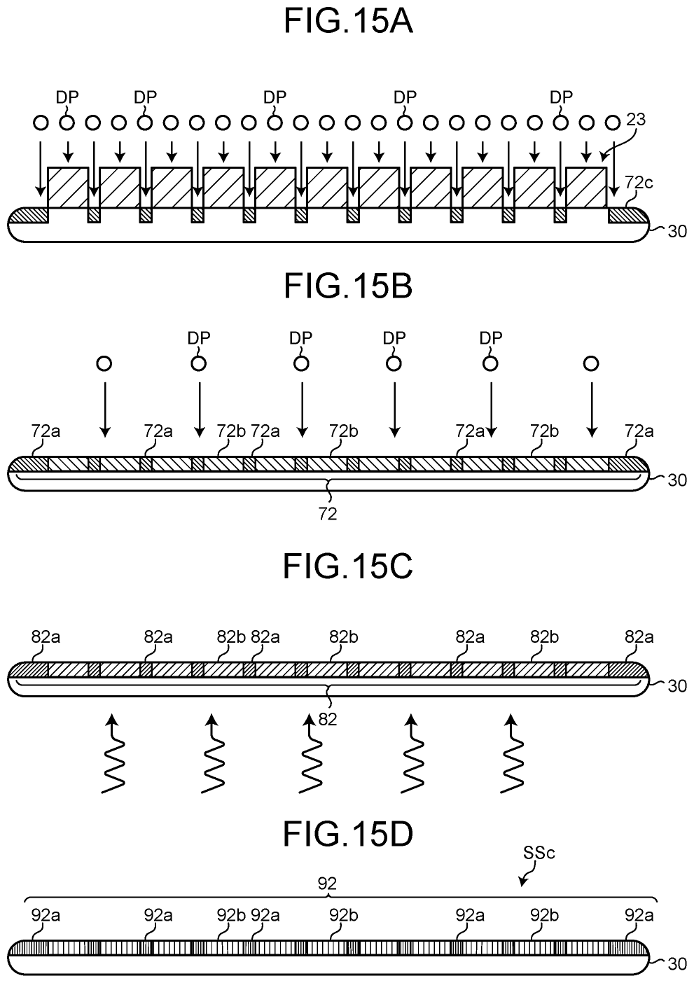

FIGS. 15A to 15D are cross-sectional views illustrating a part of the procedure of the method for manufacturing a support substrate SSc according to the second embodiment.

As illustrated in FIG. 15A, a resist pattern 23 having substantially the same pattern as the pattern of the source line SL is formed on the upper surface of the semiconductor substrate 30. Further, the dopant DP is implanted into a portion of the semiconductor substrate 30 exposed from the resist pattern 23 to form an impurity layer 72c.

Thereafter, the resist pattern 23 is removed by ashing processing using oxygen plasma or the like.

As illustrated in FIG. 15B, the dopant DP is implanted again into the entire upper surface of the semiconductor substrate 30 in which the impurity layer 72 is partially formed. As a result, the impurity layer 72 is formed on the entire upper surface of the semiconductor substrate 30. The impurity layer 72 includes impurity layers 72a and 72b having different implantation amounts of the dopant DP.

The impurity layer 72b is formed in a portion of the semiconductor substrate 30 from which the resist pattern 23 is removed, and has substantially the same pattern as the pattern of the source line SL. The impurity layer 72a is a layer which is superimposed on the impurity layer 72c formed by the processing in FIG. 15A and in which the dopant DP is implanted, and is formed to include the dopant DP having an implantation amount higher than that of the impurity layer 72b in a region between patterns of the impurity layer 72b.

As illustrated in FIG. 15C, the semiconductor substrate 30 on which the impurity layer 72 including the impurity layer 72a and the impurity layer 72b is formed is annealed to activate the dopant DP in the impurity layer 72, thereby forming active layer 82.

As a result, the active layer 82 is also formed to include an active layer 82b having the same pattern as the pattern of the source line SL and an active layer 82a having lower resistance than the active layer 82b in the region between the patterns of the active layer 82b.

As illustrated in FIG. 15D, the semiconductor substrate 30 on which the active layer 82 including the active layer 82a and the active layer 82b is formed is subjected to the anodization treatment in the same manner as in the first embodiment described above to form a porous layer 92 on the upper surface of the semiconductor substrate 30.

As a result, the porous layer 92 also includes a porous layer 92b having a pattern as the same first pattern as the pattern of source lines SL, and a porous layer 92a having a higher porosity than the porous layer 92b in the region between the patterns of the porous layer 92b.

As described above, the support substrate SSc of the second embodiment is manufactured.

The support substrate SSc of the second embodiment is also used, for example, for manufacturing the semiconductor memory device 1 as described below.

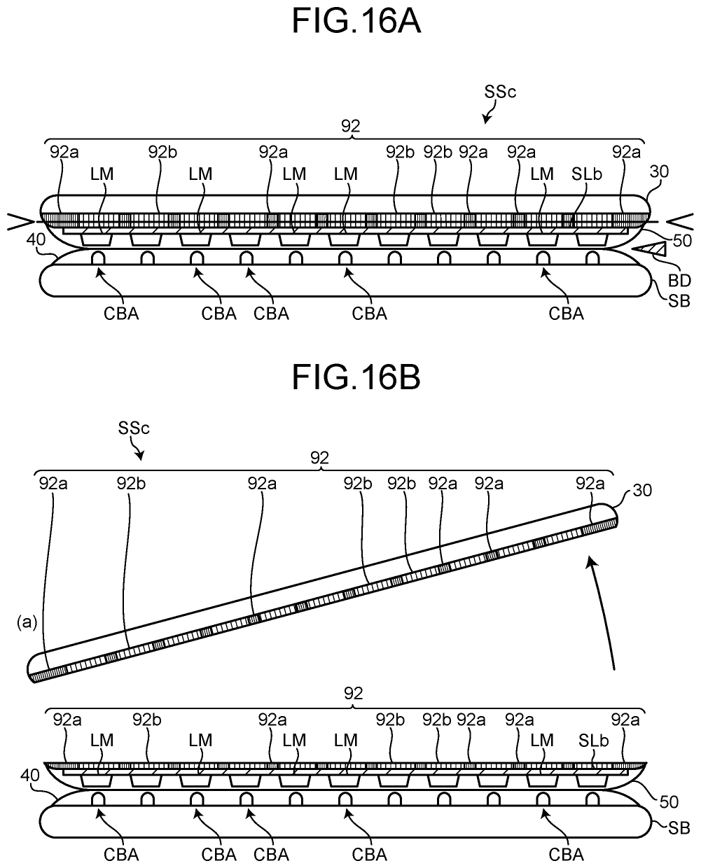

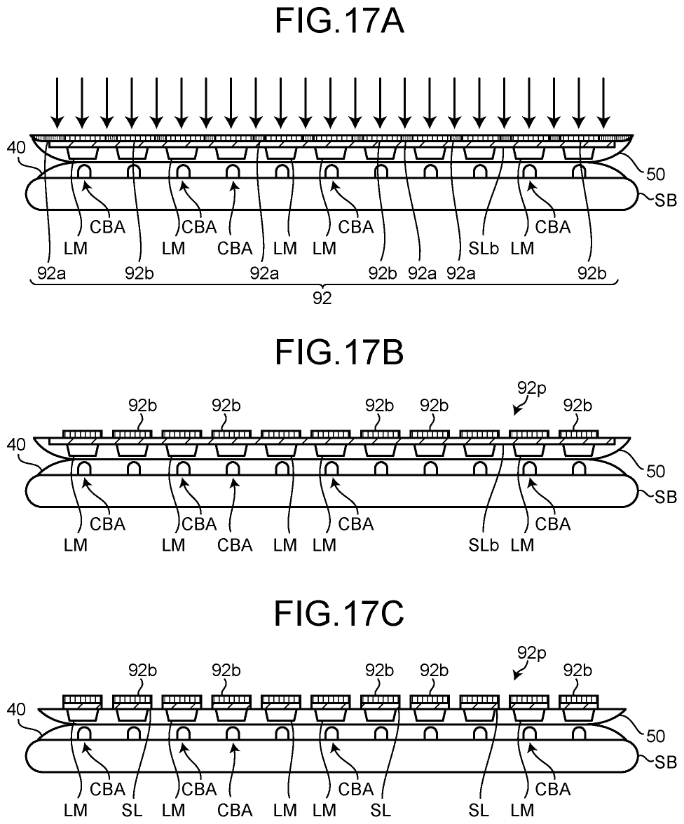

FIGS. 16A to 17C are cross-sectional views sequentially illustrating a part of the procedure of the method for manufacturing the semiconductor memory device according to the second embodiment.

As illustrated in FIG. 16A, a plurality of stacked bodies LM including a plurality of pillars PL, a plurality of contacts CC, and the like are formed on the support substrate SSc, and the semiconductor substrate SB on which a peripheral circuit CBA is formed is bonded. When the plurality of stacked bodies LM is formed on the support substrate SSc, alignment is performed such that the individual stacked bodies LM are arranged in accordance with the pattern of the porous layer 92b of the support substrate SSc.

After the support substrate SSc on which the plurality of stacked bodies LM and the like are formed is bonded to the semiconductor substrate SB, the blade BD is inserted into these bonding surfaces, or water jet is injected.

As illustrated in FIG. 16B, as described above, the porous layer 92 is cleaved, and the support substrate SSc is peeled off.

As illustrated in FIG. 17A, the porous layer 92 remaining on the conductive layer SLb of the stacked body LM bonded on the semiconductor substrate SB is processed by etching back of the entire surface using dry etching, wet etching, or the like.

As illustrated in FIG. 17B, the porous layer 92a having a high porosity is selectively removed out of the porous layers 92a and 92b included in the porous layer 92 by the above processing. As a result, a porous pattern 92p in which the porous layer 92b remains in the pattern of the source line SL is formed on the conductive layer SLb.

As illustrated in FIG. 17C, the conductive layer SLb is etched using the porous pattern 92p as a mask to form a pattern of a plurality of source lines SL separated for each stacked body LM.

After the source line SL is formed in a predetermined pattern, the porous pattern 92p is ground and removed by CMP or the like to expose the source line SL.

Note that the processing of FIGS. 17A and 17B may be collectively performed by using a condition that the selection ratio between the porous layer 92 and the conductive layer SLb is low. In such a process, the porous layer 92a of the porous layer 92 is initially preferentially removed, and thereafter, the conductive layer SLb can be processed into the source line SL of a predetermined pattern using the remaining porous layer 92b as a mask.

In addition, by using a condition that the selection ratio between the porous layer 92 and the conductive layer SLb is low, all the porous layer 92 may disappear at the time when the source line SL is formed in a predetermined pattern. In this case, the processing of FIG. 17C can be omitted.

Thereafter, the electrode film EL connected to the source line SL via the plug PG formed in the insulating layer 60 is formed, and the semiconductor substrate SB is divided so as to include at least one stacked body LM, whereby the semiconductor memory device of the second embodiment is manufactured.

According to the method for manufacturing the semiconductor memory device of the second embodiment, the porous layer 92b having a predetermined porosity is formed in the pattern of the source line SL, and the porous layer 92a having a porosity higher than that of the porous layer 92b is formed in the region between the patterns of the porous layer 92b. As a result, the pattern of the source line SL can be formed using the porous pattern 92p as a mask.

In the first embodiment described above, for example, after the porous layer 90 is removed, the conductive layer SLb is formed in the pattern of the source line SL using, as a mask, the resist pattern 21 formed on the upper surface of the conductive layer SLb. In this case, in order to align the resist pattern 21 with the plurality of stacked bodies LM and the like already formed, for example, an alignment mark is formed in advance in the same layer as the stacked body LM. However, it may be difficult to visually recognize the mark formed on the lower layer from above the conductive layer SLb.

With the support substrate SSc of the second embodiment, the plurality of stacked bodies LM are formed in accordance with the porous layer 92b having the pattern of the source line SL. Therefore, the above problem regarding the visibility of the mark can be solved.

### (Modification)

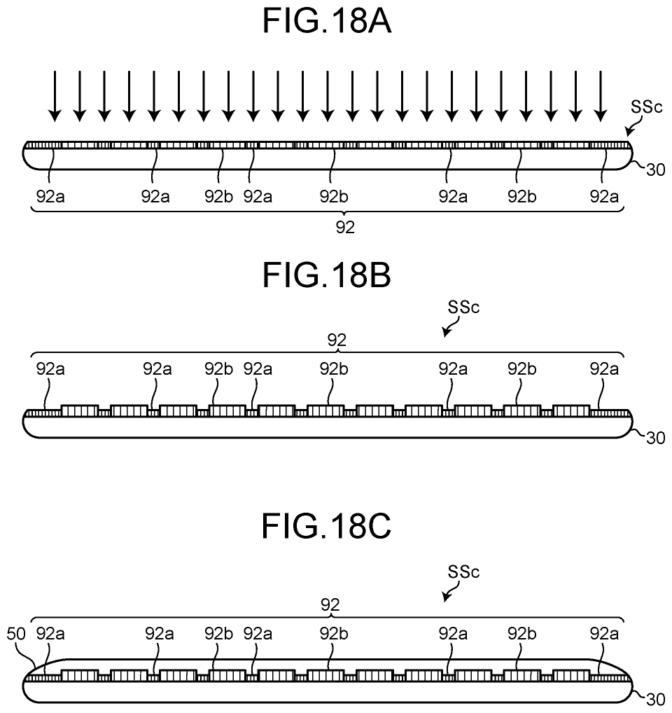

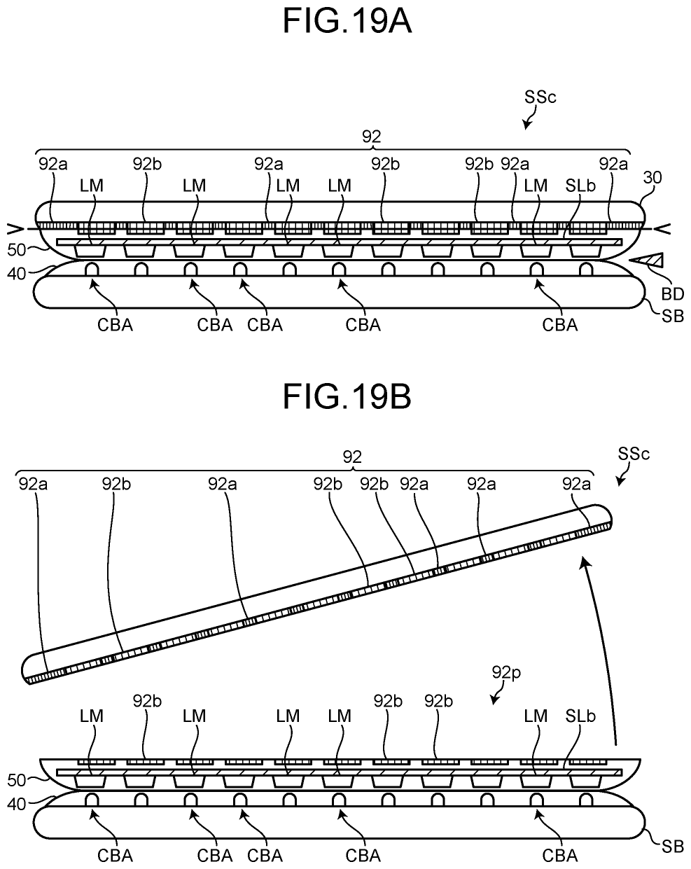

Next, a method for manufacturing the semiconductor memory device according to a modification of the second embodiment will be described with reference to FIGS. 18A to 19B.

As described below, at least a part of the processing illustrated in FIG. 17A of the second embodiment described above may be performed after the processing of FIG. 15D. An example of this case is illustrated in FIGS. 18A to 19B. In the following drawings, the same reference numerals are given to the same configurations as those of the second embodiment described above, and the description thereof may be omitted.

FIGS. 18A to 19B are cross-sectional views sequentially illustrating a part of the procedure of the method for manufacturing the semiconductor memory device according to the modification of the second embodiment.

As illustrated in FIG. 18A, after the support substrate SSc is formed by the processing of FIG. 15D, the entire surface of the support substrate SSc is etched back or wet etched to half-etch the porous layer 92a of the porous layer 92.

As illustrated in FIG. 18B, the porous layer 92a is partially removed in the layer thickness direction by the above processing.

As illustrated in FIG. 18C, a part of the insulating layer 50 is formed on the support substrate SSc side so as to fill the recess between the plurality of porous layers 92b generated by partially removing the porous layer 92a. As a result, the unevenness of the surface of the support substrate SSc is backfilled to become a flat surface.

As illustrated in FIG. 19A, a plurality of stacked bodies LM including a plurality of pillars PL, a plurality of contacts CC, and the like are formed on the support substrate SSc, and the semiconductor substrate SB on which a peripheral circuit CBA is formed is bonded. In addition, the blade BD is inserted into the bonding surface between the support substrate SSc and the semiconductor substrate SB, or water jet is injected.

As illustrated in FIG. 19B, as described above, the porous layer 92 is cleaved, and the support substrate SSc is peeled off. At this time, it is preferable that the porous layer 92a remaining in the half-etching processing of FIG. 18A described above is peeled off together with the support substrate SSc. As a result, the porous pattern 92p of the porous layer 92b is formed on the upper surface of the semiconductor substrate SB including the stacked body LM and the like.

Thereafter, using the porous pattern 92p as a mask, the insulating layer 50 between the plurality of porous layers 92b is penetrated to expose a part of the conductive layer SLb, and the exposed conductive layer SLb is etched. Thus, the source line SL is formed in a predetermined pattern.

As described above, the semiconductor memory device of the modification is manufactured.

According to the method for manufacturing the semiconductor memory device of the modification, the same effects as those of the method for manufacturing the semiconductor memory device of the second embodiment are obtained.

In the modification described above, the porous pattern 92p is formed from the porous layer 92 of the support substrate SSc using the support substrate SSc of the second embodiment. However, the porous layer 90 may be formed in a predetermined pattern using the support substrate SS or the like having the porous layer 90 having a uniform porosity as described in the first embodiment and the like. In this case, the porous layer 90 can be etched using the resist pattern having the pattern of the source line SL as a mask instead of the processing illustrated in FIG. 18A.

### Other Embodiments

In the first and second embodiments and the first and second modifications described above, the contact region ER is arranged at both end portions in the X direction of the stacked body LM. However, the arrangement position of the contact region ER in the stacked body LM is not limited thereto. The contact region ER may be arranged, for example, in a central portion of the stacked body LM, and in this case, for example, the memory region MR can be arranged at both end portions of the stacked body LM.

In the first and second embodiments and the first and second modifications described above, the support substrates SS and SSa to SSc are used for manufacturing the semiconductor memory device 1 using the substrate bonding technique. However, the support substrates SS and SSa to SSc are not limited to the case of manufacturing the semiconductor memory device 1 described above, and can be applied to manufacturing processes of various semiconductor devices.

In addition, the method for manufacturing the support substrates SS and SSa to SSc of the first and second embodiments and the first and second modifications described above may be used for manufacturing a silicon on insulator (SOI) substrate or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, comprising:
forming, on a substrate, an active layer in which a dopant is implanted;
forming a porous layer by making the active layer porous by an anodization treatment;
forming a device layer including at least a part of a configuration of the semiconductor device above the porous layer; and
cleaving the porous layer to remove the substrate.

2. The method for manufacturing a semiconductor device according to claim 1, wherein
the device layer includes:
a first conductive layer;
a stacked body positioned above the first conductive layer, the stacked body including a plurality of second conductive layers stacked; and
a memory pillar penetrating the stacked body and connected to the first conductive layer.

3. The method for manufacturing a semiconductor device according to claim 2, further comprising:
before removing the substrate,
forming a peripheral circuit including a transistor on a first semiconductor substrate; and
bonding a surface of the substrate on which the device layer is formed and a surface of the first semiconductor substrate on which the peripheral circuit is formed.

4. The method for manufacturing a semiconductor device according to claim 1, wherein
when the active layer is formed, implanting the dopant a plurality of times.

5. The method for manufacturing a semiconductor device according to claim 1, wherein
when forming the active layer, making an implantation amount of the dopant different in a plane of the substrate; and
when forming the porous layer, making a porosity of the porous layer different in the plane of the substrate depending on the implantation amount of the dopant.

6. The method for manufacturing a semiconductor device according to claim 5, wherein
when forming the active layer, making an implantation amount of the dopant in an edge region on one end side of the substrate higher than an implantation amount of the dopant in other regions;
when forming the porous layer, making the porosity on the one end side higher than the porosity of the other region; and
when removing the substrate, cleaving the porous layer from the one end side.

7. The method for manufacturing a semiconductor device according to claim 2, wherein
when forming the porous layer,
forming a first porous layer having a first porosity in a first pattern, and
forming a second porous layer having a second porosity higher than the first porosity in regions in gaps of the first pattern;
when forming the stacked body,
forming the stacked body in a region overlapping the first pattern; and
when removing the substrate,
cleaving the porous layer while leaving a part of the porous layer on a surface of the first conductive layer; and the method further comprising:
after removing the substrate,
forming the first conductive layer in the first pattern in accordance with the first pattern of the stacked body and
when forming the first conductive layer in the first pattern,
using, as a mask, the first porous layer in the porous layer remaining on the surface of the first conductive layer.

8. The method for manufacturing a semiconductor device according to claim 7, wherein
when forming the first conductive layer in the first pattern,
removing the second porous layer after removing the substrate; and
processing the first conductive layer using, as a mask, the first porous layer after removing the second porous layer.

9. The method for manufacturing a semiconductor device according to claim 1, wherein
the substrate is a second semiconductor substrate, and
when forming the active layer, implanting the dopant into a surface of the second semiconductor substrate and activating the dopant by annealing treatment.

10. The method for manufacturing a semiconductor device according to claim 1, wherein
when forming the active layer,
forming a semiconductor layer on the substrate; and
implanting the dopant into the semiconductor layer and activating the dopant by annealing treatment.

11. A method for manufacturing a support substrate, comprising:
forming, on a substrate, an active layer in which a dopant is implanted; and
forming a porous layer by making the active layer porous by an anodization treatment.

12. The method for manufacturing a support substrate according to claim 11, wherein
when forming the active layer, controlling acceleration energy for implanting the dopant to control a layer thickness of the active layer.

13. The method for manufacturing a support substrate according to claim 11, wherein
when forming the active layer, controlling an implantation amount of the dopant to control a resistance value of the active layer.

14. The method for manufacturing a support substrate according to claim 11, wherein
when forming the active layer, implanting the dopant a plurality of times.

15. The method for manufacturing a support substrate according to claim 11, wherein
when forming the active layer, making an implantation amount of the dopant in an edge region on one end side of the substrate higher than an implantation amount of the dopant in other regions; and
when forming the porous layer, making a porosity on the one end side higher than a porosity of the other region.

16. The method for manufacturing a support substrate according to claim 11, wherein
the substrate is a second semiconductor substrate, and
when forming the active layer, the dopant is implanted into a surface of the second semiconductor substrate and activating the dopant by annealing treatment.

17. The method for manufacturing a support substrate according to claim 11, wherein
when forming the active layer,
forming a semiconductor layer on the substrate;
implanting the dopant into the semiconductor layer; and
activating the dopant by annealing treatment.

18. The method for manufacturing a support substrate according to claim 17, wherein
the semiconductor layer is
a polycrystalline layer or an amorphous layer formed on the substrate, or
a single crystal layer epitaxially grown from a surface of the substrate.

19. The method for manufacturing a support substrate according to claim 11, further comprising:
cleaving the porous layer to peel the substrate; and
planarizing a surface of the peeled substrate so as to regenerate the substrate.

20. A method for peeling a substrate, comprising:
forming, on a substrate, an active layer in which a dopant is implanted;
forming a porous layer by making the active layer porous by an anodization treatment;
forming a first layer above the porous layer; and
cleaving the porous layer to peel off the substrate.
